(19) United States
(12) Patent Application Publication
(10) Pub. No.: US 2012/0080800 A1
(43) Pub. Date: Apr. 5, 2012

(54) POWER MODULE AND METHOD FOR MANUFACTURING THE SAME

(75) Inventor: Toshiaki SHINOHARA, Tokyo (JP)

(73) Assignee: MITSUBISHI ELECTRIC CORPORATION, Tokyo (JP)

(21) Appl. No.: 13/164,031

(22) Filed: Jun. 20, 2011

(30) Foreign Application Priority Data
Oct. 1, 2010 (JP) 2010-223505

(51) Int. Cl. H01L 23/48; H01L 21/56

(52) U.S. Cl. 257/773; 438/124; 257/E23.01; 257/E21.502

(57) ABSTRACT

Provided is a power module that prevents a deterioration of reliability of bonded portions of aluminum wires, and enables a high-temperature operation of a Si or SiC device. A power module according to the present invention includes: insulating substrates arranged in a case; power elements bonded on the insulating substrates; wiring members as first wiring members which are rectangular tube-like metal, and have first side surfaces bonded to surface electrodes of the power elements; aluminum wires as wires connected to second side surfaces of the wiring members, which are opposite to the first side surfaces, and a sealing material filled into the case while covering the insulating substrates, the power elements, the wiring members and the aluminum wires.

### BACKGROUND OF THE INVENTION

1. Field of the Invention

The present invention relates to a power module and a method for manufacturing the same, and particularly, relates to a power module operated at high temperature and a method for manufacturing the same.

2. Description of the Background Art

In a conventional power module, in usual, a insulating substrate is formed of ceramics such as aluminum nitride (hereinafter, AlN, alumina (Al₂O3), and silicon nitride (Si₃N₄), and a metal pattern such as copper or aluminum is formed on front and back surfaces of the insulating substrate. Power elements arranged on the insulating substrate are bonded by solder onto such metal pattern of the insulating substrate, wiring is made from electrodes of the power elements to terminal portions by aluminum wires, and the power modules is entirely sealed by a sealing material such as silicone gel. A configuration example of this power module is described in Japanese Patent Application Laid-Open No. H06-5742 (1994).

When the power module is operated, a current flows through resistor components of the power elements, and the elements generate heat. This heat passes through the insulating substrates, the solder and a base plate to an external radiator, and is then radiated.

However, bonded portions of the aluminum wires bonded to the power elements have a problem that temperature thereof rises by receiving the heat of the power elements, resulting in a decrease of reliability of the bonded portions. Moreover, in some cases, the bonded portions have a problem that a thermal stress is repeatedly applied thereto due to a difference between a thermal expansion coefficient (linear expansion coefficient) of the power elements and a thermal expansion coefficient (linear expansion coefficient) of the aluminum wires, and fatigue breakage occurs in the vicinity of interfaces therebetween, resulting in a fracture. In particular, in a device such as a SiC device capable of a high-temperature operation, operation temperature further rises, and the reliability of the bonded portions is significantly decreased.

### SUMMARY OF THE INVENTION

It is an object of the present invention to provide a power module that prevents a deterioration of the reliability of the bonded portions of the aluminum wires, and enables the high-temperature operation of the Si or SiC device, and to provide a method for manufacturing the power module.

A power module according to the present invention includes an insulating substrate arranged in a case, a power element bonded onto the insulating substrate, a first wiring member as rectangular tube-like metal, the first wiring member having a first side surface bonded to a surface electrode of the power element, a wire connected to a second side surface of the first wiring member, the second side surface being opposite to the first side surface, and a sealing material filled into the case while covering the insulating substrate, the power element, the first wiring member and the wire.

In accordance with the power module according to the present invention, a distance between the surface of the power element and the bonded portion of the wire is increased, the heat can be suppressed from directly passing therebetween, and the deterioration of the reliability of the bonded portions can be prevented. Moreover, the thermal stress due to the difference between the thermal expansion coefficient of the power elements and that of the wire is suppressed, and fracture possibility of such bonding can be suppressed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a power module according to Embodiment 1;

FIGS. 2 and 3 are cross-sectional views of a wiring member according to Embodiment 1;

FIG. 4 is a cross-sectional view of a power module according to Embodiment 2;

FIG. 5 is a cross-sectional view of a power module according to Embodiment 3; and

FIG. 6 is a cross-sectional view of a power module according to the underlying technology.

### DESCRIPTION OF THE PREFERRED EMBODIMENTS

First, a power module according to the underlying technology of the present invention is described below.

As shown in FIG. 6, in a case 8, the power module includes a base plate 7, insulating substrates 5 arranged on the base plate 7 while interposing solder 6 therebetween, power elements 1 arranged on the insulating substrates 5 while interposing the solder 6 therebetween, terminals 4 connected to surface electrodes of the power elements 1 while interposing aluminum wires 3 therebetween, and a sealing material 2 filled into the case 8 while covering the insulating substrates 5, the power elements 1 and the aluminum wires 3.

When the power module is operated, a current flows through resistor components of the power elements 1, and the power elements 1 generate heat. This heat passes through the insulating substrates 5, the solder 6 and the base plate 7 to an external radiator (not shown), and is then radiated therefrom.

However, bonded portions of the aluminum wires 3 bonded to the power elements 1 have a problem that temperature thereof rises by receiving the heat of the power elements 1, resulting in a decrease of reliability of bonding thereof. Moreover, in some cases, the bonded portions have a problem that a thermal stress is repeatedly applied thereto due to a difference between a thermal expansion coefficient (linear expansion coefficient) of the power elements 1 and that of the aluminum wires 3, and fatigue breakage occurs in the vicinity of interfaces therebetween, resulting in a fracture. In particular, in a device such as a SiC device capable of a high-temperature operation, an operation temperature further rises, and the reliability of the bonded portions is significantly decreased.

In the following preferred embodiments, a power module that solves such problems is described.

### A. Embodiment 1

### A-1. Configuration

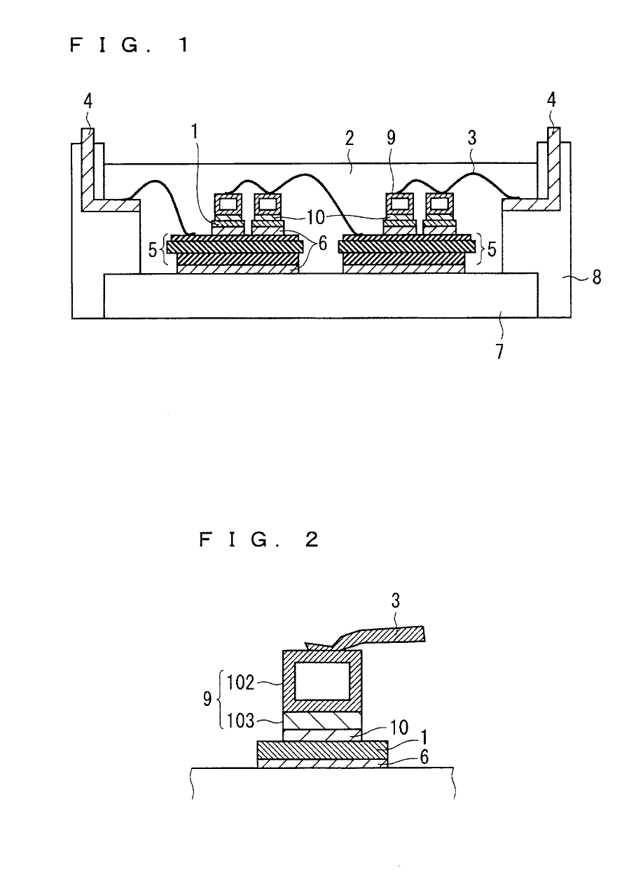

A power module according to Embodiment 1 of the present invention is described with reference to the drawings. As shown in FIG. 1, in a case 8, the power module according to the present invention includes a base plate 7, insulating substrates 5 arranged individually on the base plate 7 while interposing solder 6 therebetween, power elements 1 arranged on the insulating substrates 5 while interposing the solder 6 therebetween, wiring members 9 as first wiring members bonded to surface electrodes of the power elements 1 while interposing a bonding material 10 therebetween, terminals 4 connected to the wiring members 9 while interposing aluminum wires 3 as wires therebetween, and a sealing material 2 filled into the case 8 while covering the insulating substrates 5, the power elements 1, the wiring members 9 and the aluminum wires 3. SiC or the like, which is a wide band gap semiconductor, is used as the power elements 1, whereby a device capable of a higher-temperature operation can be realized.

The wiring members 9 are made of, for example, a copper material or a copper alloy material, which has good electric conductivity, and a shape thereof is a rectangular tube shape. One main surface (first side surface) of each of the wiring members 9 is bonded to a surface electrode portion of each of the power elements 1 by the bonding material 10 that is, for example, a low-temperature sintering material such as solder, silver and copper. The aluminum wire 3 is bonded to a main surface (second side surface) of each of the wiring members 9, which is opposite to the one main surface. As a material of the wiring members 9, a material having a larger thermal expansion coefficient (linear expansion coefficient) than a thermal expansion coefficient (linear expansion coefficient) of the power elements 1 is selected. The wiring member 9 has an effect of absorbing the heat generated in the power elements 1 though not being required to adopt such an insulating structure as required for a cooling medium electrode allowing a cooling medium to be inserted through a tube.

The aluminum wire 3 may also be sheet-like aluminum ribbon or copper wire, or copper ribbon wire.

In Embodiment 1, the thermal conductivity of the sealing material 2 is increased, whereby heat radiation properties from the wiring members 9 are enhanced, and the temperature of the bonded portions of the aluminum wires 3 can be further reduced. As a method for enhancing the thermal conductivity from the sealing material 2, it is possible to mix powder of silica, alumina, silicon nitride, aluminum nitride, boron nitride or the like into the sealing material 2.

FIG. 2 shows a structure of each of the wiring members 9 mounted on the power elements 1 of Embodiment 1. A metal material 102 that composes the rectangular wiring member 9 is composed of copper or a copper alloy, which has good electric conductivity, and a side surface (first side surface) thereof bonded to the power element 1 is composed by combining therewith a low expansive material 103 having a linear expansion coefficient approximate to the linear expansion coefficient (6.6×10⁻⁶/K) of SiC as the material of the power element 1. In such a way, a thermal stress in the bonding material 10, which occurs due to the difference in thermal expansion coefficient between the power element 1 and the wiring member 9, is reduced, and a fatigue lifetime of the bonding material 10 can be extended.

As the low expansive material 103 as described above, a material with a linear expansion coefficient approximately ranging from 4×10⁻⁶/K to 10×10⁻⁶/K is desirable, and for example, a cladding material (linear expansion coefficient: 7×10⁻⁶/K) formed by bonding copper with a thickness ratio of 1 to both sides of invar with a thickness ratio of 3 is adaptive. In the cladding material as described above, the thickness ratio of invar and copper is adjusted, whereby a desired thermal expansion coefficient (linear expansion coefficient) can be obtained. Brazing, welding and the like are usable for bonding the low expansive material 103 and the wring member 9 to each other.

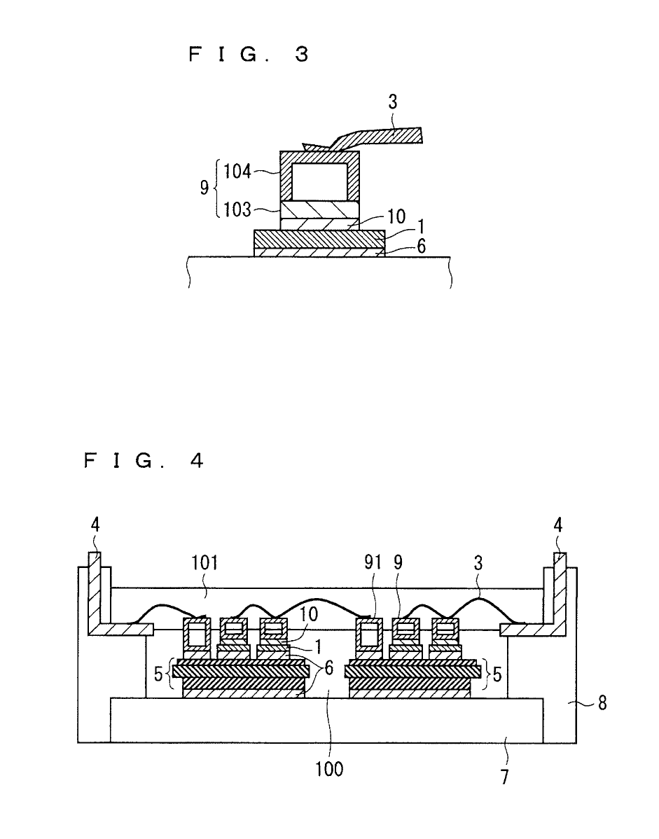

A wiring member 9 in FIG. 3 is similar to the wiring member 9 shown in FIG. 2; however, a side surface (first side surface) thereof bonded to the power element 1 is composed only of the low expansive material 103, and the wiring member 9 in FIG. 3 is formed by bonding, to the low expansive material 103, a metal material 104 such as copper having a thermal expansion coefficient approximate to that of aluminum so that a rectangular tube shape can be formed from end portions of the first side surface. With such a configuration, it becomes possible to further enhance the reliability of the bonding material 10.

### A-2. Effect

In accordance with Embodiment 1 according to the present invention, the power module includes the insulating substrates 5 arranged in the case 8, the power elements 1 bonded onto the insulating substrates 5, the wiring members 9 as the first wiring members which are the rectangular tube-like metal, in which the first side surfaces are bonded to the surface electrodes of the power elements 1, the aluminum wires 3 as the wires connected to the second side surfaces of the wiring members 9, which are opposite to the first side surfaces, and the sealing material 2 filled into the case 8 while covering the insulating substrates 5, the power elements 1, the wiring members 9 and the aluminum wires 3. In such a way, a distance between the surfaces of the power elements 1 and the bonded portions of the aluminum wires 3 is increased, the heat can be suppressed from directly passing therebetween, and a deterioration of reliability of such bonded portions can be prevented. Moreover, the thermal stress due to the difference between the thermal expansion coefficient of the power elements 1 and the thermal expansion coefficient of the aluminum wires 3 is suppressed, and the fracture possibility of the bonding can be suppressed.

Moreover, in accordance with Embodiment 1 according to the present invention, in the power module, the thermal expansion coefficient of the wiring member 9 as the first wiring members is larger than the thermal expansion coefficient of the power elements 1. In such a way, the thermal stress owing to the difference between the thermal expansion coefficient of the power elements 1 and the thermal expansion coefficient of the aluminum wires 3 is suppressed, and the fracture possibility of the bonding can be suppressed.

Furthermore, in accordance with Embodiment 1 according to the present invention, in the power module, in the wiring members 9 as the first wiring members, the low expansive material 103 as members corresponding to the first side surfaces thereof is a member having a lower thermal expansion coefficient than the metal materials 102 and 104 as members corresponding to other side surfaces. In such way, a stress in the bonding material 10, which occurs due to the difference in thermal expansion coefficient between the power elements 1 and the wiring members 9, is reduced, and the fatigue lifetime of the bonding material 10 can be extended.

Moreover, in accordance with Embodiment 1 according to the present invention, in the power module, the power elements 1 are the wide band gap semiconductor elements, whereby it becomes possible to realize a device capable of the higher-temperature operation.

### B. Embodiment 2

### B-1. Configuration

FIG. 4 shows a power module according to Embodiment 2. As shown in FIG. 4, in addition to the configuration of the power module shown in Embodiment 1, the power module according to Embodiment 2 includes wiring members 91 as second wiring members which are rectangular tube-like metal, and have first side surfaces bonded onto surface patterns of the insulating substrates 5. In the power module, the wiring members 91 and the terminals 4 are connected to each other while interposing the aluminum wires 3 therebetween.

Here, in a similar way to Embodiment 1, it is possible to fill the sealing material 2 into the case 8. However, in this Embodiment 2, the case 8 is filled with a sealing material 100 (first sealing material) such as epoxy resin so that at least the side surfaces (second side surfaces) where the aluminum wires 3 are bonded to the wiring members 9 and the wiring members 91 can be exposed, followed by curing of the sealing material 100, and thereafter, the aluminum wires 3 are bonded to exposed surfaces of the wiring members 9 and the wiring members 91. Thereafter, a sealing material 101 (second sealing material) for ensuring insulating properties is filled into an exposed portion as the rest. Note that a filling height of the sealing material 100 is adjustable by setting strength to be described later, and so on.

By adopting such a configuration, a structure capable of enduring a load and ultrasonic vibrations, which are applied at the time of bonding the aluminum wires 3, is realized, so that more stable bonding properties are obtained, and quality is enhanced. Moreover, the wiring members 9 and the wiring members 91 can be fixed by the sealing material 100, and accordingly, a height of the wiring members 9 and the wiring members 91 can be maintained to be high, whereby the temperature of the bonded portions of the aluminum wires 3 can be decreased.

Such a method of filling the sealing material 100 and the sealing material 101 is applicable even to the case of a structure in which the wiring members 91 are not provided on the insulating substrates 5 (that is, the structure of Embodiment 1).

### B-2. Effect

In accordance with Embodiment 2 according to the present invention, the sealing material 2 includes: the sealing material 100 as the first sealing material filled into the case 8 while covering the insulating substrates 5, the power elements 1 and the wiring members 9 so that at least the second side surfaces of the wiring members 9 as the first wiring members can be exposed, and the sealing material 101 as the second sealing material further filled onto the sealing material 100 while covering at least the second side surfaces of the wiring members 9 and the aluminum wires 3 as the wires. In such a way, the structure capable of enduring the load and the ultrasonic vibrations, which are applied at the time of bonding the aluminum wires 3, is realized, so that more stable bonding properties are obtained, and the quality is enhanced. Moreover, the wiring members 9 and the wiring members 91 can be fixed by the sealing material 100, and accordingly, the height of the wiring members 9 and the wiring members 91 can be maintained to be high, so that the temperature of the bonded portions of the aluminum wires 3 can be decreased.

Moreover, in accordance with Embodiment 2 according to the present invention, the power module further includes the wiring members 91 as the second wiring members which are the rectangular tube-like metal, and have first side surfaces bonded onto the surface patterns of the insulating substrates 5. In the power module, the sealing material 100 as the first sealing member is filled while covering the wiring members 91 so that at least the second side surfaces of the wiring members 91 as the second wiring members, which are opposite to the first side surfaces, can be exposed, and the sealing material 101 as the second sealing material is filled while covering at least the second side surfaces of the wiring members 91. In such a way, the distance between the power elements 1 and the bonded portions of the aluminum wires 3 is increased, whereby a heat radiation effect is enhanced, and the reliability of the bonded portions can be enhanced. Moreover, the structure capable of enduring the load and the ultrasonic vibrations, which are applied at the time of bonding the aluminum wires 3, is realized, so that more stable bonding properties are obtained, and the quality is enhanced.

Furthermore, in accordance with Embodiment 2 according to the present invention, in the power module, the sealing material 2 is the epoxy resin, whereby the thermal conductivity of the sealing material is enhanced, whereby the heat radiation effect can be enhanced.

Moreover, in accordance with Embodiment 2 according to the present invention, a method for manufacturing the power module includes (a) filling the sealing material 100 as the first sealing material into the case 8 while covering the insulating substrates 5, the power elements 1 and the wiring members 9 so that at least the second side surfaces of the wiring members 9 as the first wiring members can be exposed, (b) connecting the aluminum wires 3 as the wires to the second side surfaces of the wiring members 9, which are exposed after the case 8 is filled with the sealing material 100, and (c) further filling the sealing material 101 as the second sealing material onto the sealing material 100 while covering at least the second side surfaces of the wiring members 9 and the aluminum wires 3. In such a way, the structure capable of enduring the load and the ultrasonic vibrations, which are applied at the time of bonding the aluminum wires 3, is realized, so that more stable bonding properties are obtained, and the quality is enhanced.

### C. Embodiment 3

### C-1. Configuration

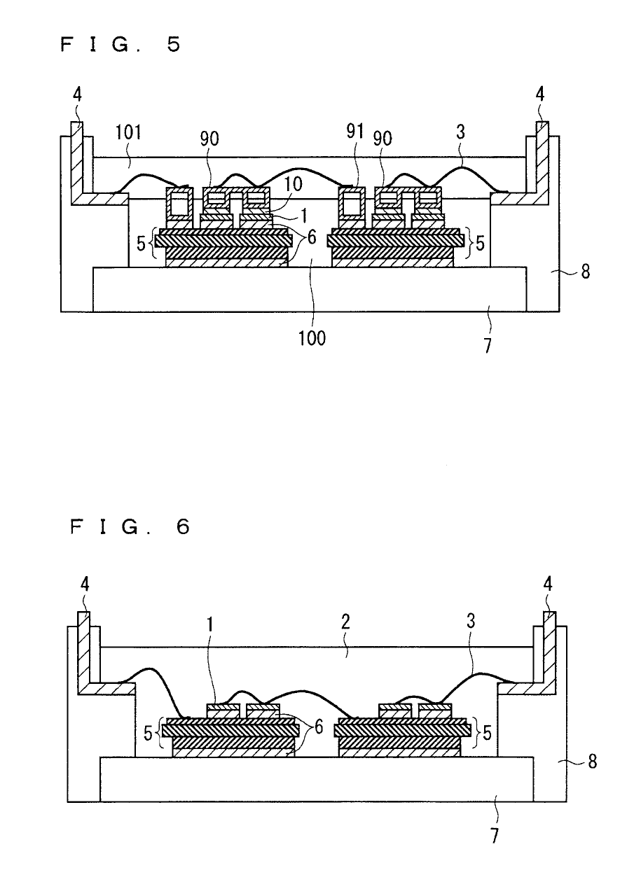

FIG. 5 shows a power module according to Embodiment 3 in the case of using a plurality of the power elements in parallel connection. As shown in FIG. 5, in addition to the configuration of the power module shown in Embodiment 2, the power module according to this Embodiment 3 includes wiring members 90 provided to correspond to the respective power elements 1, the wiring members 90 being bonded to each other on the second surface side.

The wiring members 90 have an integral structure lying astride the plurality of power elements 1. With such a configuration, the strength for enduring the load and the ultrasonic vibrations, which are applied at the time of bonding the aluminum wires 3, is increased more than in the case of Embodiment 2, and moreover, since connection portions are formed, an area of a surface from which the heat is radiated is also increased, and accordingly, a further heat radiation effect can be expected.

### C-2. Effect

In accordance with Embodiment 3 according to the present invention, in the power module, the plurality of power elements 1 are arranged on the insulating substrate 5, the wiring members 90 as the first wiring members are provided to correspond to the plurality of power elements 1, the respective first side surfaces of the wiring members 90 are bonded to the respective surface electrodes of the plurality of power elements 1 in a corresponding manner, and the respective second surfaces of the respective wiring members 90 are bonded to each other. In such a way, the strength for enduring the load and the ultrasonic vibrations, which are applied at the time of bonding the aluminum wires 3, is further increased, and moreover, since the connection portions are formed, the area of the surface from which the heat is radiated is also increased, and accordingly, the further heat radiation effect can be expected.

In the embodiments of the present invention, materials of the respective constituent elements, embodying conditions and the like are also described; however, these are illustrations, and materials and the like in the present invention are not limited to those described above.

While the invention has been shown and described in detail, the foregoing description is in all aspects illustrative and not restrictive. It is therefore understood that numerous modifications and variations can be devised without departing from the scope of the invention.

What is claimed is:

1. A power module comprising:
an insulating substrate arranged in a case;
a power element bonded onto said insulating substrate;
a first wiring member as rectangular tube-like metal, the first wiring member having a first side surface bonded to a surface electrode of said power element;
a wire connected to a second side surface of said first wiring member, the second side surface being opposite to the first side surface; and
a sealing material filled into said case while covering said insulating substrate, said power element, said first wiring member and said wire.

2. The power module according to claim 1,
wherein a thermal expansion coefficient of said first wiring member is larger than a thermal expansion coefficient of said power element.

3. The power module according to claim 1,
wherein, in said first wiring member, a member corresponding to said first side surface is a member having a thermal expansion coefficient lower than a thermal expansion coefficient of members corresponding to other side surfaces.

4. The power module according to claim 1,
wherein said sealing material includes:
a first sealing material filled into said case while covering said insulating substrate, said power element and said first wiring member so that at least said second side surface of said first wiring member can be exposed; and
a second sealing material further filled onto said first sealing material while covering at least said second side surface of said first wiring member and said wire.

5. The power module according to claim 4, further comprising:
a second wiring member as rectangular tube-like metal, the second wiring member having a first side surface bonded to a surface pattern of said insulating substrate,
wherein said first sealing material is filled while covering said second wiring member so that at least a second side surface of said second wiring member, the second side surface being opposite to said first side surface, can be exposed, and
the said second sealing material is filled while covering at least said second side surface of said second wiring member.

6. The power module according to claim 1,
wherein said sealing material is epoxy resin.

7. The power module according to claim 1,
wherein a plurality of the power elements are arranged on said insulating substrate,
the said first wiring member is provided to correspond to said plurality of power elements, and respective pieces of said first side surfaces are bonded to respective pieces of the surface electrodes of said plurality of power elements in a corresponding manner, and
respective pieces of said second side surfaces of said first wiring member are bonded to each other.

8. The power module according to claim 1,
wherein said power element is a wide band gap semiconductor element.

9. A method for manufacturing a power module including an insulating substrate arranged in a case, a power element bonded onto said insulating substrate, a first wiring member as rectangular tube-like metal, the first wiring member having a first side surface bonded to a surface electrode of said power element, a wire connected to a second side surface of said first wiring member, the second side surface being opposite to said first side surface, and a sealing material filled into said case while covering said insulating substrate, said power element, said first wiring member and said wire, in which said sealing material includes a first sealing material filled into the case while covering said insulating substrate, said power element and said first wiring member so that at least said second side surface of said first wiring member can be exposed, and a second sealing material further filled onto said first sealing material while covering at least said second side surface of said first wiring member and said wire,
the method comprising:
(a) filling said first sealing material into said case while covering said insulating substrate, said power element and said first wiring member so that at least said second side surface of said first wiring member can be exposed;
(b) connecting said wire to said second side surface of said first wiring member, the second side surface being exposed after the case is filled with said first sealing material; and
(c) further filling said second sealing material onto said first sealing material while covering at least said second side surface of said first wiring member and said wire.
